(19) United States
(12) Patent Application Publication
(10) Pub. No.: US 2008/0238504 A1
(43) Pub. Date: Oct. 2, 2008

(54) Phase locked loop

(75) Inventor: Dae-Han Kwon, Kyoungki-do (KR)

Correspondence Address: BLAKELY SOKOLOFF TAYLOR & ZAFMAN LLP, 1279 OAKMEAD PARKWAY, SUNNYVALE, CA, 94085-4040, US

(73) Assignee: Hynix Semiconductor Inc.

(21) Appl. No.: 11/998,894

(22) Filed: Dec. 3, 2007

(30) Foreign Application Priority Data
Mar. 31, 2007 (KR) 10-2007-0032089

(51) Int. Cl. H03L 7/06

(52) U.S. Cl. 327/156

(57) ABSTRACT

A phase locked loop includes a first clock divider configured to divide a first input clock to generate a second input clock; a clock selector configured to selectively output one of the first input clock and the second input clock in response to a test signal; a phase/frequency detector configured to detect phase and frequency differences between the selected output clock of the clock selector and a feedback clock to generate a detection signal corresponding to the detected phase and frequency differences; a control voltage generator configured to generate a control voltage having a voltage level corresponding to the detection signal; a voltage controlled oscillator configured to generate an internal clock having a frequency corresponding to the control voltage; and a second clock divider configured to divide the internal clock to generate the feedback clock.

### CROSS-REFERENCE TO RELATED APPLICATIONS

The present invention claims priority of Korean patent application number 10-2007-0032089, filed on Mar. 31, 2007, which is incorporated by reference in its entirety.

### BACKGROUND OF THE INVENTION

The present invention relates to a semiconductor device, and more particularly, to a phase locked loop (PLL) that can generate a desired high-frequency clock in both a normal mode and a test mode.

In semiconductor devices such as double data rate (DDR) synchronous dynamic random access memory (SDRAM), an external clock (CLK_EXT) is used as a reference to match an operation timing. However, a clock skew may occur in the external clock (CLK_EXT) due to the delay of clock/data path within internal circuits. In order to compensate the clock skew, a clock synchronization circuit is provided within the semiconductor device. Examples of the clock synchronization circuit include a phase locked loop (PLL) and a delay locked loop (DLL). The semiconductor device transmits/receives signals to/from external devices by using an internal clock (CLK_INN) outputted from the clock synchronization circuit.

The PLL is mainly used when the frequency of the external clock (CLK_EXT) is different from the frequency of the internal clock (CLK_INN), and the DLL is mainly used when the frequency of the external clock (CLK_EXT) is equal to the frequency of the internal clock (CLK_INN). The configuration of the PLL is basically similar to that of the DLL. The PLL uses a voltage controlled oscillator (VCO) to generate the internal clock (CLK_INN), while the DLL uses a voltage controlled delay line (VCDL).

Specially, the PLL is used in a variety of applications, e.g., communications, wireless systems, digital circuits, etc. The PLL can generate various clocks through frequency synthesis and can easily achieve a clock data recovery (CDR). Hence, the PLL is widely used, even though it occupies a larger chip area and is difficult to design. As the operating speed of the chip is increasing, the PLL is essential to designing high-speed semiconductor devices with high operating frequency. It is expected that the application fields of the PLL will be widely expanded with rapid development of semiconductor device design technology.

FIG. 1 is a block diagram of a typical PLL.

As shown, the PLL includes a clock buffer 100, a phase/frequency detector 110, a control voltage generator 120, and a voltage controlled oscillator (VCO) 130.

The clock buffer 100 buffers an external clock CLK_EXT to output a reference clock CLK_REF. The phase/frequency detector 110 detects phase and frequency differences between the reference clock CLK_REF and a feedback clock CLK_FED to generate up and down detection signals DET_UP and DET_DN corresponding to the detected phase and frequency differences. The control voltage generator 120 generates a control voltage V_CTR having a voltage level corresponding to the up and down detection signals DET_UP and DET_DN. The VCO 130 generates an internal clock CLK_INN having a frequency corresponding to the control voltage V_CTR. The frequency of the internal clock CLK_INN is equal to that of the feedback clock CLK_FED.

An operation of the PLL will be described below.

The phase/frequency detector 110 compares the frequency of the reference clock CLK_REF with the frequency of the feedback clock CLK_FED. When the frequency of the reference clock CLK_REF is higher than that of the feedback clock CLK_FED, the phase/frequency detector 110 outputs the up detection signal DET_UP having a pulse width corresponding to the phase and frequency differences between the reference clock CLK_REF and the feedback clock CLK_FED. On the other hand, when the frequency of the reference clock CLK_REF is lower than that of the feedback clock CLK_FED, the phase/frequency detector 110 outputs the down detection signal DET_DN having a pulse width corresponding to the phase and frequency differences between the feedback clock CLK_FED and the reference clock CLK_REF. The control voltage generator 120 increases the voltage level of the control voltage V_CTR in response to the up detection signal DET_UP and decreases the voltage level of the control voltage V_CTR in response to the down detection signal DET_DN. The VCO 130 generates the internal clock CLK_INN having the frequency corresponding to the voltage level of the control voltage V_CTR. The internal clock CLK_INN is fed back to the phase/frequency detector 110 as the feedback clock CLK_FED, and the phase/frequency detector 110 compares the frequency of the reference clock CLK_REF with the frequency of the feedback clock CLK_REF.

The PLL repeats the above-mentioned PLL operation to generate the internal clock CLK_INN having the frequency corresponding to the reference clock CLK_REF.

Since circuit configurations of the clock buffer 100, the phase/frequency detector 110, the control voltage generator 120, and the VCO 130 are well known, their detailed description will be omitted for conciseness.

A semiconductor device having the PLL undergoes a variety of tests. After passing the tests, an actual external clock (hereinafter, referred to as “a system clock”) is inputted to the PLL. The PLL performs the PLL operation to generate the internal clock CLK_INN having a desired frequency and the internal circuits use the internal clock CLK_INN, thereby stably performing its operation.

Upon the test operation, an external clock used in the test operation (hereinafter, referred to as “a test clock”) is inputted to the PLL. Therefore, the PLL can generate a stable internal clock CLK_INN in a user system when the frequency of the test clock is equal to that of the system clock.

When assuming that a test apparatus can generate a test clock of up to 1 GHz, the test apparatus can test semiconductor devices using a system clock of less than 1 GHz. In other words, the PLL can generate the normal internal clock CLK_INN of less than 1 GHz using the test clock of less than 1 GHz.

However, it is difficult to test semiconductor devices that use the system clock of more than 1 GHz. In other words, the PLL of the semiconductor device using the system clock of 2 GHz can test if the internal clock CLK_INN of 1 GHz is generated using the test clock of 1 GHz, but cannot test if the normal internal clock CLK_INN is generated using the system clock.

In order to address these problems, test apparatus must be able to generate the test clock of more than 1 GHz, e.g., 2 GHz. However, this adds a significant economic burden to users because they must additionally purchase new test apparatus. Therefore, there is a need for PLLs that can overcome these problems in a current environment of higher operating frequency.

### SUMMARY OF THE INVENTION

Embodiments of the present invention are directed to providing a PLL configured to receive a low-frequency test clock to generate a high-frequency internal clock in a test mode.

Embodiments of the present invention are also directed to providing a PLL configured to receive a system clock to generate a desired internal clock.

In accordance with an aspect of the present invention, there is provided a phase locked loop, including: a first clock divider configured to divide a first input clock to generate a second input clock; a clock selector configured to selectively output one of the first input clock and the second input clock in response to a test signal; a phase/frequency detector configured to detect phase and frequency differences between the selected output clock of the clock selector and a feedback clock to generate a detection signal corresponding to the detected phase and frequency differences; a control voltage generator configured to generate a control voltage having a voltage level corresponding to the detection signal; a voltage controlled oscillator configured to generate an internal clock having a frequency corresponding to the control voltage; and a second clock divider configured to divide the internal clock to generate the feedback clock.

In accordance with another aspect of the present invention, there is provided a phase locked loop, including: a phase/frequency detector configured to detect phase and frequency differences between an input clock and a first feedback clock to output a detection signal corresponding to the detected phase and frequency differences; a control voltage generator configured to generate a control voltage having a voltage level corresponding to the detection signal; a voltage controlled oscillator configured to generate an internal clock having a frequency corresponding to the control voltage; a clock divider configured to divide the internal clock to generate a second feedback clock; and a clock selector configured to selectively output one of the internal clock and the second feedback clock as the first feedback clock in response to a test signal.

In accordance with further another aspect of the present invention, there is provided a phase locked loop, including: a phase/frequency detector for detecting phase and frequency differences between a first input clock and a second input clock to generate a detection signal corresponding to the detected phase and frequency differences; a control voltage generator for generating a control voltage having a voltage level corresponding to the detection signal; a voltage controlled oscillator for generating an internal clock having a frequency corresponding to the control voltage; and a clock controller for adjusting the first input clock and the second input clock to generate a desired high-frequency clock in both a normal mode and a test mode.

In a test mode, a phase locked loop can determine if a semiconductor device operates normally by generating a high-frequency internal clock using a low-frequency test clock. In a normal mode, the phase locked loop can ensure a normal circuit operation by generating the high-frequency internal clock using the high-frequency system clock. Hence, an additional cost of purchasing new apparatus can be saved because the phase locked loop operation of the phase locked loop of the semiconductor device using the high-frequency system clock can be tested without changing the test apparatus.

### BRIEF DESCRIPTION OF THE DRAWINGS

FIG. 1 is a block diagram of a typical PLL;

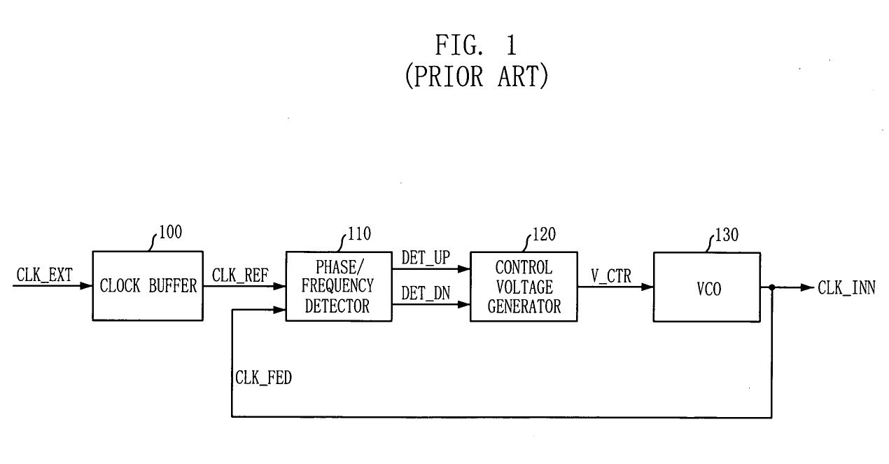

FIG. 2 is a block diagram of a PLL in accordance with a first embodiment of the present invention; and

FIG. 3 is a block diagram of a PLL in accordance with a second embodiment of the present invention.

### DESCRIPTION OF SPECIFIC EMBODIMENTS

Hereinafter, a phase locked loop (PLL) capable of generating a desired high-frequency clock in both a normal mode and a test mode in accordance with the present invention will be described in detail with reference to the accompanying drawings.

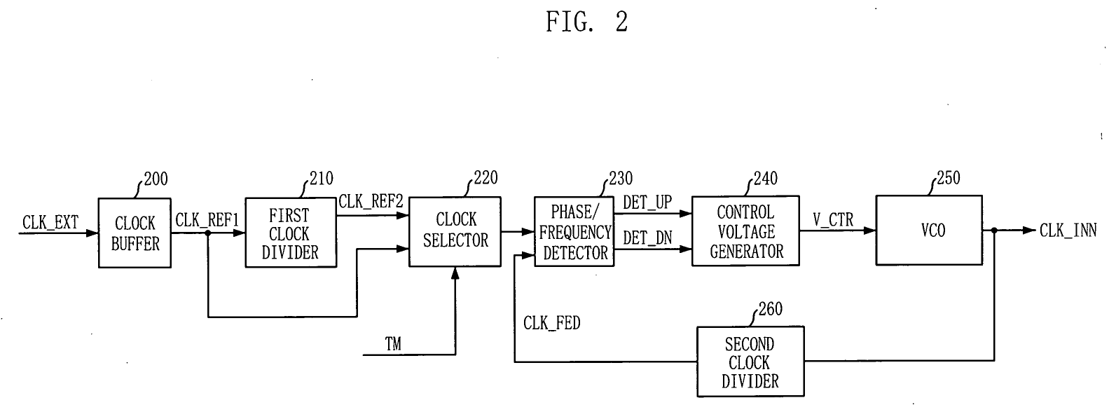

FIG. 2 is a block diagram of a PLL in accordance with a first embodiment of the present invention.

As shown, the PLL includes a clock buffer 200, a first clock divider 210, a clock selector 220, a phase/frequency detector 230, a control voltage generator 240, a voltage controlled oscillator (VCO) 250, and a second clock divider 260.

The clock buffer 200 buffers an external clock CLK_EXT to output a first reference clock CLK_REF1. The first clock divider 210 divides the first reference clock CLK_REF1 to generate a second reference clock CLK_REF2. The clock selector 220 selectively outputs one of the first reference clock CLK_REF1 and the second reference clock CLK_REF2 in response to a test signal TM. The phase/frequency detector 230 detects phase and frequency differences between an output of the clock selector 220 and a feedback clock CLK_FED and generates up and down detection signals DET_UP and DET_DN corresponding to the detected phase and frequency differences. The control voltage generator 240 generates a control voltage V_CTR having a voltage level corresponding to the up and down detection signals DET_UP and DET_DN. The VCO 250 generates an internal clock CLK_INN having a frequency corresponding to the control voltage V_CTR. The second clock divider 260 divides the internal clock CLK_INN to generate the feedback clock CLK_FED.

Hereinafter, a process of testing the PLL is defined as a test mode, and a process of using the PLL after the testing is defined as a normal mode. The external clock CLK_EXT inputted in the test mode is referred to as a test clock, and the external clock CLK_EXT inputted in the normal mode is referred to as a system clock. In addition, the test clock is a low frequency clock that can be generated by a test apparatus, and the system clock is a clock having a frequency higher than that of the test clock. It is assumed that the test signal TM has a logic high level in the test mode and a logic low level in the normal mode. Further, it is assumed that the division ratio of the first and second dividers 210 and 260 is ½.

In the test mode in which the test signal TM has a logic high level, the clock buffer 200 buffers the low-frequency test clock CLK_EXT to generate the first reference clock CLK_REF1. The clock selector 220 outputs the first reference clock CLK_REF1 in response to the test signal TM of the logic high level. The phase/frequency detector 230 outputs the up and down detection signals DET_UP and DET_DN corresponding to the phase and frequency differences between the first reference clock CLK_REF1 and the feedback clock CLK_FED. The control voltage generator 240 generates the control voltage V_CTR corresponding to the up and down detection signals DET_UP and DET_DN, and the VCO 250 generates the internal clock CLK_INN having the frequency corresponding to the control voltage V_CTR. The second clock divider 260 divides the internal clock CLK_INN to generate the feedback clock CLK_FED, and the phase/frequency detector 230 compares the frequency of the first reference clock CLK_REF1 with the frequency of the feedback clock CLK_FED fed back from the second clock divider 260.

For example, when testing the PLL using the system clock of 2 GHz, the PLL must be able to generate the internal clock CLK_INN of 2 GHz. The phase/frequency detector 230 generates the up and down detection signals DET_UP and DET_DN having pulse width corresponding to the phase and frequency differences between the first reference clock CLK_REF1 of 1 GHz, which is the frequency of the test clock, and the feedback clock CLK_FED. The control voltage generator 240 generates the control voltage V_CTR having a voltage level corresponding to the up and down detection signals DET_UP and DET_DN. The VCO 250 generates the internal clock CLK_INN having the frequency corresponding to the control voltage V_CTR, and the second clock divider 260 divides the internal clock CLK_INN to generate and output the feedback clock CLK_FED to the phase/frequency detector 230.

The PLL repeats the PLL operation until the feedback clock CLK_FED becomes 1 GHz. That is, the PLL operation is performed until the internal clock CLK_INN from the VCO 250 becomes 2 GHz. Consequently, in the test mode, the internal clock CLK_INN of 2 GHz can be generated by using the test clock of 1 GHz and the feedback clock CLK_FED which is divided by the second clock divider 260.

Meanwhile, in the normal mode in which the test signal TM has a logic low level, the clock buffer 200 buffers the high-frequency system clock CLK_EXT to generate the first reference clock CLK_REF1. The first clock divider 210 divides the first reference clock CLK_REF1 to generate the second reference clock CLK_REF2. The clock selector 220 outputs the second reference clock CLK_REF2 in response to the test signal TM of the logic low level. The phase/frequency detector 230 outputs the up and down detection signals DET_UP and DET_DN corresponding to the phase and frequency differences between the second reference clock CLK_REF2 and the feedback clock CLK_FED. The control voltage generator 240 generates the control voltage V_CTR corresponding to the up and down detection signals DET_UP and DET_DN, and the VCO 250 generates the internal clock CLK_INN having the frequency corresponding to the control voltage V_CTR. The second clock divider 260 divides the internal clock CLK_INN to generate the feedback clock CLK_FED, and the phase/frequency detector 230 compares the frequency of the second reference clock CLK_REF2 with the frequency of the feedback clock CLK_FED fed back from the second clock divider 260.

For example, when testing the PLL using the system clock of 2 GHz, the PLL must be able to generate the internal clock CLK_INN of 2 GHz. The phase/frequency detector 230 generates the up and down detection signals DET_UP and DET_DN having pulse width corresponding to the phase and frequency differences between the second reference clock CLK_REF2 of 1 GHz, which is a division of the system clock of 2 GHz, and the feedback clock CLK_FED. The control voltage generator 240 generates the control voltage V_CTR having a voltage level corresponding to the up and down detection signals DET_UP and DET_DN. The VCO 250 generates the internal clock CLK_INN having the frequency corresponding to the control voltage V_CTR. The second clock divider 260 divides the internal clock CLK_INN to generate the feedback clock CLK_FED.

The PLL repeats the PLL operation until the feedback clock CLK_FED becomes 1 GHz. That is, the PLL operation is performed until the internal clock CLK_INN from the VCO 250 becomes 2 GHz. Consequently, in the normal mode, the internal clock CLK_INN of 2 GHz can be generated by using the second reference clock CLK_REF2, which is a division of the system clock of 2 GHz, and the feedback clock CLK_FED.

The test signal TM may be a signal distinguishing the test mode from the normal mode. Further, the test signal TM may be a signal having frequency information. In other words, when testing a semiconductor device using a low-frequency system clock, it is preferable that the test signal TM has the logic low level just like in the normal mode.

In this embodiment, a basic clock divider may be further provided on the feedback path of the PLL. The basic clock divider is configured to produce a feedback frequency lower than an output frequency so as to using a crystal oscillator as a reference frequency source. The crystal oscillator is an oscillator that can maintain an accurate reference frequency even in the change of environment. The basic clock divider may be disposed at the front or rear of the second clock divider 260. Furthermore, it is possible to implement a single divider having a division ratio corresponding to the product of the division ratio of the second clock divider 260 and the division ratio of the basic clock divider.

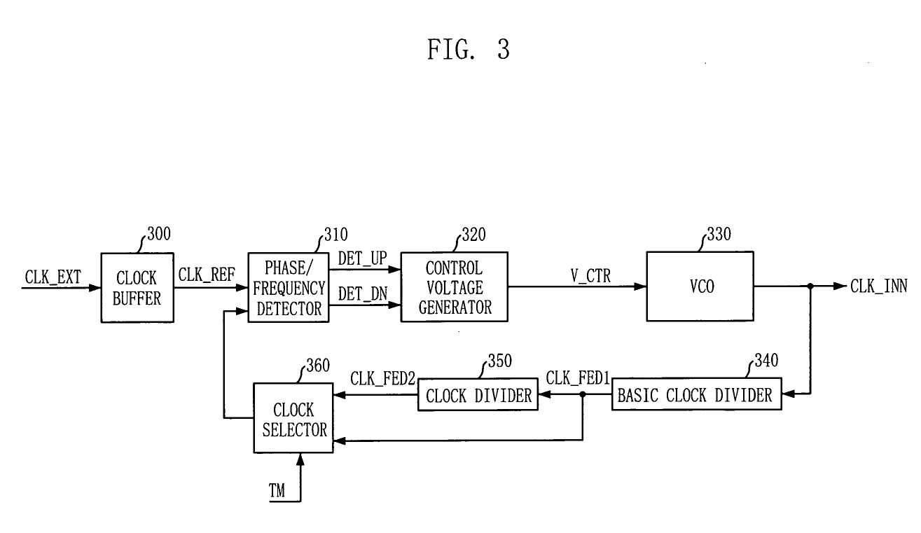

FIG. 3 is a block diagram of a PLL in accordance with a second embodiment of the present invention.

As shown, the PLL includes a clock buffer 300, a phase/frequency detector 310, a control voltage generator 320, a VCO 330, a clock divider 350, and a clock selector 360.

The clock buffer 300 buffers an external clock CLK_EXT to generate a reference clock CLK_REF. The phase/frequency detector 310 detects a phase and frequency differences between the reference clock CLK_REF and an output of the clock selector 360 and generates up and down detection signals DET_UP and DET_DN corresponding to the detected phase and frequency differences. The control voltage generator 320 generates a control voltage V_CTR having a voltage level corresponding to the up and down detection signals DET_UP and DET_DN. The VCO 330 generates an internal clock CLK_INN having a frequency corresponding to the control voltage V_CTR. The clock divider 350 divides a first feedback clock CLK_FED1 corresponding to the internal clock CLK_INN to generate a second feedback clock CLK_FED2. The clock selector 360 selectively outputs one of the first feedback clock CLK_FED1 and the second feedback clock CLK_FED2 in response to the test signal TM.

In this embodiment, the PLL may further include a basic clock divider 340 configured to generate a desired internal clock CLK_INN using a low-frequency reference clock. The basic clock divider 340 may be disposed between the VCO 330 and the clock divider 350 to divide the internal clock CLK_INN by a predefined basic division ratio to generate the first feedback clock CLK_FED1. In addition, the basic clock divider 340 may be disposed between the clock selector 360 and the phase/frequency detector 310 to divide the output clock of the clock selector 360 by a predefined basic division ratio and provide the division clock to the phase/frequency detector 310.

Like in the first embodiment, the test clock is a low frequency clock that can be generated by a test apparatus, and the system clock is a clock having a frequency higher than that of the test clock. It is assumed that the test signal TM has a logic high level in the test mode and a logic low level in the normal mode. In addition, it is assumed that the division ratio of the clock divider 350 is ½ and the division ratio of the basic clock divider 340 is 1.

In the test mode, the clock buffer 300 buffers the low-frequency test clock CLK_EXT to generate the reference clock CLK_REF. The phase/frequency detector 310 detects the phase and frequency differences between the reference clock CLK_REF and the output clock of the clock selector 360 and outputs the up and down detection signals DET_UP and DET_DN corresponding to the detected phase and frequency differences. The control voltage generator 320 generates the control voltage V_CTR corresponding to the up and down detection signals DET_UP and DET_DN. The VCO 330 generates the internal clock CLK_INN as the first feedback clock CLK_FED1 having the frequency corresponding to the control voltage V_CTR. The clock divider 350 divides the first feedback clock CLK_FED1 to generate the second feedback clock CLK_FED2. The clock selector 360 outputs the second feedback clock CLK_FED2 in response to the test signal TM. The phase/frequency detector 310 compares the second feedback clock CLK_FED2 with the reference clock CLK_REF. In this way, the PLL operation is repeated.

Like in the first embodiment, the PLL in accordance with the second embodiment of the present invention repeats the PLL operation until the feedback clock CLK_FED becomes 1 GHz. That is, the PLL operation is performed until the internal clock CLK_INN from the VCO 330 becomes 2 GHz. Consequently, in the test mode, the internal clock CLK_INN of 2 GHz can be generated using the test clock of 1 GHz and the feedback clock CLK_FED. It is possible to test if the semiconductor device generates the stable internal clock CLK_INN of 2 GHz.

In the normal mode, the clock buffer 300 buffers the high-frequency system clock CLK_EXT to generate the reference clock CLK_REF. The phase/frequency detector 310 detects a frequency difference between the reference clock CLK_REF and the output clock of the clock selector 360 and outputs detection signals DET_UP and DET_DN corresponding to the detected frequency difference. The control voltage generator 320 generates a control voltage V_CTR corresponding to the detection signals DET_UP and DET_DN. The VCO 330 generates the internal clock CLK_INN as the first feedback clock CLK_FED1 having the frequency corresponding to the control voltage V_CTR. The clock selector 360 outputs the first feedback clock CLK_FED1 in response to the test signal TM. The phase/frequency detector 310 compares the first feedback clock CLK_FED1 with the reference clock CLK_REF. In this way, the PLL operation is repeated.

The PLL repeats the PLL operation until the feedback clock CLK_FED becomes 1 GHz. That is, the PLL operation is performed until the internal clock CLK_INN from the VCO 330 becomes 2 GHz. Consequently, in the normal mode, the internal clock of 2 GHz can be generated using the system clock of 2 GHz and the feedback clock CLK_RED, which is not divided.

Like in the first embodiment, the test signal TM may be a signal distinguishing the test mode from the normal mode. Further, the test signal TM may be a signal having frequency information. In other words, when testing a semiconductor device using a low-frequency system clock, it is preferable that the test signal TM has the logic low level just like in the normal mode.

As described above, in the test mode, the PLL can determine if the semiconductor device operates normally by generating the high-frequency internal clock CLK_INN using the low-frequency test clock. In the normal mode, the PLL can ensure the normal circuit operation by generating the internal clock CLK_INN using the high-frequency system clock.

An additional cost of purchasing new apparatus can be saved because the PLL operation of the PLL of the semiconductor device using the high-frequency system clock can be tested without changing the test apparatus.

Moreover, the circuit diversity can be increased because the desired PLL operation can be performed in both the test mode and the normal mode.

While the present invention has been described with respect to the specific embodiments, it will be apparent to those skilled in the art that various changes and modifications may be made without departing from the spirit and scope of the invention as defined in the following claims.

What is claimed is:

1. A phase locked loop, comprising:
a first clock divider configured to divide a first input clock to generate a second input clock;
a clock selector configured to selectively output one of the first input clock and the second input clock in response to a test signal;
a phase/frequency detector configured to detect phase and frequency differences between the selected output clock of the clock selector and a feedback clock to generate a detection signal corresponding to the detected phase and frequency differences;
a control voltage generator configured to generate a control voltage having a voltage level corresponding to the detection signal;
a voltage controlled oscillator configured to generate an internal clock having a frequency corresponding to the control voltage; and
a second clock divider configured to divide the internal clock to generate the feedback clock.

2. The phase locked loop as recited in claim 1, further comprising a buffer configured to buffer an external clock to output the first input clock.

3. The phase locked loop as recited in claim 1, wherein the clock selector outputs the second input clock when a frequency of the first input clock is higher than that of a reference frequency, and outputs the first input clock when the frequency of the first input clock is equal to or lower than that of the reference frequency.

4. The phase locked loop as recited in claim 1, wherein the test signal has frequency information of the first input clock.

5. A phase locked loop, comprising:
a phase/frequency detector configured to detect phase and frequency differences between an input clock and a first feedback clock to output a detection signal corresponding to the detected phase and frequency differences;
a control voltage generator configured to generate a control voltage having a voltage level corresponding to the detection signal;
a voltage controlled oscillator configured to generate an internal clock having a frequency corresponding to the control voltage;
a clock divider configured to divide the internal clock to generate a second feedback clock; and
a clock selector configured to selectively output one of the internal clock and the second feedback clock as the first feedback clock in response to a test signal.

6. The phase locked loop as recited in claim 5, further comprising a buffer configured to buffer an external clock to output the input clock.

7. The phase locked loop as recited in claim 5, wherein the clock selector outputs the internal clock when a frequency of the input clock is higher than that of a reference frequency, and outputs the second feedback clock when the frequency of the input clock is equal to or lower than that of the reference frequency.

8. The phase locked loop as recited in claim 5, wherein the test signal has frequency information of the input clock.

9. The phase locked loop as recited in claim 5, further comprising a basic clock divider configured to divide an output clock of the voltage controlled oscillator by a predefined basic division ratio.

10. The phase locked loop as recited in claim 5, further comprising a basic clock divider configured to divide an output clock of the clock selector by a predefined basic division ratio.

11. The phase locked loop as recited in claim 10, wherein the clock selector outputs the internal clock when a frequency of the input clock is higher than that of a reference frequency, and outputs the second feedback clock when the frequency of the input clock is equal to or lower than that of the reference frequency.

12. The phase locked loop as recited in claim 10, wherein the test signal has frequency information of the input clock.

13. A phase locked loop, comprising:
a phase/frequency detector for detecting phase and frequency differences between a first input clock and a second input clock to generate a detection signal corresponding to the detected phase and frequency differences;
a control voltage generator for generating a control voltage having a voltage level corresponding to the detection signal;
a voltage controlled oscillator for generating an internal clock having a frequency corresponding to the control voltage; and
a clock controller for adjusting the first input clock and the second input clock to generate a desired high-frequency clock in both a normal mode and a test mode.

14. The phase locked loop as recited in claim 13, wherein the clock controller includes:
an external clock divider configured to divide an external clock to generate an intermediate input clock;
a clock selector configured to select one of the external clock and the intermediate input clock to output the selected one as the first input clock in response to a test signal; and
an internal clock divider configured to divide the internal clock to generate the second input clock.

15. The phase locked loop as recited in claim 14, further comprising a buffer configured to buffer the external clock.

16. The phase locked loop as recited in claim 14, wherein the clock selector outputs the intermediate input clock when a frequency of the external clock is higher than that of a reference frequency, and outputs the external clock when the frequency of the external clock is equal to or lower than that of the reference frequency.

17. The phase locked loop as recited in claim 14, wherein the test signal has frequency information of the external clock.

18. The phase locked loop as recited in claim 13, wherein the clock controller includes:
a clock divider configured to divide the internal clock to generate an intermediate input clock; and
a clock selector configured to selectively output one of the internal clock and the intermediate input clock as the second input clock in response to a test signal.

19. The phase locked loop as recited in claim 18, further comprising a buffer configured to buffer an external clock to output the first input clock.

20. The phase locked loop as recited in claim 18, wherein the clock selector outputs the internal clock when a frequency of the first input clock is higher than that of a reference frequency, and outputs the intermediate input clock when the frequency of the first input clock is equal to or lower than that of the reference frequency.

21. The phase locked loop as recited in claim 18, wherein the test signal has frequency information of the first input clock.

22. The phase locked loop as recited in claim 18, further comprising a basic clock divider configured to divide an output clock of the voltage controlled oscillator by a predefined basic division ratio.

23. The phase locked loop as recited in claim 18, further comprising a basic clock divider configured to divide an output clock of the clock selector by a predefined basic division ratio.
